(19) United States
(12) Patent Application Publication
(10) Pub. No.: US 2026/0239596 A1
(43) Pub. Date: Aug. 13, 2026

(54) SEMICONDUCTOR DEVICE, ELECTRONIC APPARATUS INCLUDING THE SAME, AND METHOD OF MANUFACTURING SEMICONDUCTOR DEVICE

(71) Applicant: Samsung Electronics Co., Ltd., Suwon-si (KR)

(72) Inventors: Minwoo CHOI, Suwon-si (KR); Yongyoung PARK, Suwon-si (KR); Kiyeon YANG, Suwon-si (KR); Youngjae KANG, Suwon-si (KR); Younjin JANG, Suwon-si (KR)

(73) Assignee: Samsung Electronics Co., Ltd., Suwon-si (KR)

(21) Appl. No.: 19/374,588

(22) Filed: Oct. 30, 2025

(30) Foreign Application Priority Data
Feb. 11, 2025 (KR) 10-2025-0017512

(51) Int. Cl. H10B 12/00

(52) U.S. Cl. CPC H10B 12/00

(57) ABSTRACT

Disclosed are a semiconductor device, an electronic apparatus including the same, and a method of manufacturing a semiconductor device. The semiconductor device includes a channel including TeₐO_{b} (where a+b=100, 70≤a≤95, and 5≤b≤30), a source electrode electrically connected to the channel, a drain electrode electrically connected to the channel and spaced apart from the source electrode, a gate insulating layer on the channel, and a gate electrode on the gate insulating layer.

### CROSS-REFERENCE TO RELATED APPLICATION

This application is based on and claims priority under 35 U.S.C. § 119 to Korean Patent Application No. 10-2025-0017512, filed on Feb. 11, 2025, in the Korean Intellectual Property Office, the disclosure of which is incorporated by reference herein in its entirety.

### BACKGROUND

### 1. Field

The disclose relates to a semiconductor device including a p-type semiconductor channel, an electronic apparatus including the semiconductor device, and a method of manufacturing a semiconductor device.

### 2. Description of the Related Art

Most oxide semiconductors with high electrical performance used in semiconductor devices are n-type semiconductors that may efficiently transport electrons at room temperature. As an example of an n-type semiconductor, InGaZnO is widely used and is applied to backplane transistors for driving organic light-emitting diode (OLED) displays. However, the development of p-type semiconductors configured for hole transport is being explored to overcome some of the limitations in the application of the n-type semiconductors in various fields.

Materials such as SnO have been studied as p-type oxide semiconductors, but SnO may exhibit lower hole field-effect mobility and a lower ON/OFF current ratio as compared to n-type oxide semiconductors. Therefore, research on p-type oxide semiconductors with better electrical characteristics for application in various semiconductor devices is being explored.

### SUMMARY

Provided is a semiconductor device including a p-type channel.

Provided is an electronic apparatus including a semiconductor device that includes a p-type channel.

Provided is a method of manufacturing a semiconductor device including a p-type channel.

Additional aspects will be set forth in part in the description which follows and, in part, will be apparent from the description, or may be learned by practice of the presented embodiments of the disclosure.

According to at least one example embodiment, a semiconductor device includes a channel comprising TeₐO_{b}, wherein a+b=100, 70≤a≤95, and 5≤b≤30; a source electrode electrically connected to the channel; a drain electrode electrically connected to the channel and spaced apart from the source electrode; a gate electrode on the channel; and a gate insulating layer between the channel and the gate electrode.

The channel may have a structure in which a structure in which a plurality of Te layers is alternately stacked with a plurality of TeO layers.

The channel may further include at least one of S, Se, In, Sn, Cu, or Ge.

The source electrode may be spaced apart from the drain electrode in a vertical direction, and the channel, the gate insulating layer, and the gate electrode may be arranged in a horizontal direction, the horizontal direction longitudinal to the vertical direction.

The channel may include a bottom portion in contact with the source electrode, a first vertical extension portion extending from one end of the bottom portion in a vertical direction perpendicular to the source electrode, and a second vertical extension portion extending from another end of the bottom portion in the vertical direction.

The gate insulating layer may include a ferroelectric material.

The gate electrode may be a first gate electrode, and the semiconductor device may further comprise a second gate electrode spaced apart from the first gate electrode, and a spacer between the first gate electrode and the second gate electrode. The gate insulating layer may be concentric with the channel. The first gate electrode and the second gate electrode may be concentric with the gate insulating layer.

The channel may be included as one of a plurality of channels, and the semiconductor device may have a multi-bridge structure in which the plurality of channels are each in contact with the source electrode and the drain electrode and are stacked spaced apart from one another in a direction away from the substrate.

According to at least one example embodiment, an electronic apparatus includes a host, a memory device including at least one semiconductor device, and a memory controller configured to control the memory device in response to a request from the host, wherein the at least one semiconductor device includes a channel comprising TeₐO_{b}, wherein a+b=100, 70≤a≤95, and 5≤b≤30, a source electrode electrically connected to the channel, a drain electrode electrically connected to the channel and spaced apart from the source electrode, a gate electrode on the channel, and a gate insulating layer between the channel and the gate electrode. The memory controller may be configured to control the memory device to at least one of reading data from the memory device or writing data to the memory device.

The memory device may include a dynamic random-access memory (DRAM) device having a two-transistor, zero-capacitor (2T0C) structure.

According to at least one example embodiment, a method of manufacturing a semiconductor device includes forming a channel including Te and O on a substrate, adjusting a composition of the channel to TeₐO_{b}, where a+b=100, 70≤a≤95, and 5≤b≤30, forming a source electrode and a drain electrode on the channel, forming a gate insulating layer on the channel, and forming a gate electrode on the gate insulating layer such that thee gate insulating layer separates the gate electrode and the channel.

The forming of the channel may include preparing a first target including TeO and a second target including Te, and sputtering the first target and the second target in a gas atmosphere.

The method may further include controlling a deposition amount of oxygen from the TeO in the first target.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a semiconductor device according to at least one example embodiment;

FIG. 2 shows a transfer curve for a semiconductor device in a case in which an oxygen content of a TeₐO_{b} channel is 29 at %, according to at least one example embodiment;

FIG. 3 shows a transfer curve for a semiconductor device at an oxygen content of 24 at % in a TeₐO_{b} channel, according to at least one example embodiment;

FIG. 4 shows a transfer curve for a semiconductor device in a case in which an oxygen content of a TeₐO_{b} channel is 19 at %, according to at least one example embodiment;

FIG. 5 shows changes in voltage-current graphs for a semiconductor device at oxygen contents of 29 at %, 24 at %, and 19 at % in a TeₐO_{b} channel, according to at least one example embodiment;

FIG. 6 shows transconductance with respect to gate voltage for a semiconductor device at an oxygen content of 24 at % in a TeₐO_{b} channel, according to at least one example embodiment;

FIG. 7 shows transconductance with respect to gate voltage for a semiconductor device at an oxygen content of 19 at % in a TeₐO_{b} channel, according to at least one example embodiment;

FIG. 8 shows mobility for a semiconductor device at oxygen contents of 24 at % and 19 at % in a TeₐO_{b} channel, according to at least one example embodiment;

FIGS. 9, 10, and 11 illustrate examples of semiconductor devices having vertical channel structures;

FIG. 12 is a horizontal cross-sectional view schematically illustrating a structure of a memory cell string of a memory apparatus, according to at least one example embodiment;

FIG. 13 is a vertical cross-sectional view corresponding to FIG. 12;

FIG. 14 illustrates a semiconductor device having a multi-channel structure, according to at least one example embodiment;

FIGS. 15A and 15B are diagrams for describing a method of manufacturing a semiconductor device, according to at least one example embodiment;

FIG. 16 illustrates a memory apparatus to which a semiconductor device is applied, according to at least one example embodiment;

FIG. 17 is a diagram illustrating an equivalent circuit of a memory apparatus according to at least one example embodiment;

FIG. 18 is a conceptual diagram schematically illustrating a device architecture applicable to an electronic apparatus, according to at least one example embodiment;

FIG. 19 is a block diagram of a memory system according to at least one example embodiment; and

FIG. 20 is a block diagram illustrating a neuromorphic apparatus and an external device connected thereto, according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device, an electronic apparatus including the same, and a method of manufacturing a semiconductor device according to various embodiments will be described in detail with reference to the accompanying drawings. In the drawings, like reference numerals refer to like elements, and sizes of elements in the drawings may be exaggerated for clarity and convenience of description. Terms such as “first” and “second” may be used to describe various elements, but the elements should not be limited by the terms. These terms are only used to distinguish one element from another element.

The singular expression also includes the plural meaning as long as it is not inconsistent with the context. In addition, when an element is referred to as “including” a component, the element may additionally include other components rather than excluding other components as long as there is no particular opposing recitation. In addition, in the drawings, the size or thickness of each element may be exaggerated for clarity of description. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical and/or geometric values.

It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. Also, it will also be understood that when a material layer is referred to as being “on” another substrate or layer, it can be directly on the other substrate or layer, or intervening layers may also be present. In addition, materials constituting each layer in the following embodiments are exemplary, and other materials than the described ones may also be used.

In addition, as used herein, terms such as “ . . . er (or)”, “ . . . unit”, “ . . . module”, etc., which denote a unit that performs at least one function or operation, which may be implemented as and/or include processing circuitry such as hardware or software or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. Also, connecting lines or connecting members illustrated in the drawings are intended to represent example functional relationships and/or physical or logical connections between the various elements. It should be noted that many alternative or additional functional relationships, physical connections or logical connections may be present in a practical device.

The particular implementations shown and described herein are examples of the disclosure and are not intended to otherwise limit the scope of the disclosure in any way. For the sake of brevity, related-art electronics, control systems, software and other functional aspects of the systems may not be described in detail. Furthermore, line connections or connection members between elements depicted in the drawings represent functional connections and/or physical or circuit connections by way of example, and in actual applications, they may be replaced or embodied with various suitable additional functional connections, physical connections, or circuit connection”.

The term “the” and other demonstratives similar thereto should be understood to include a singular form and plural forms.

The operations of a method may be performed in any suitable order unless otherwise indicated herein or otherwise clearly contradicted by context. In addition, all example terms (e.g., “such as” or “etc.”) are used for the purpose of description and are not intended to limit the scope of the disclosure unless defined by the claims.

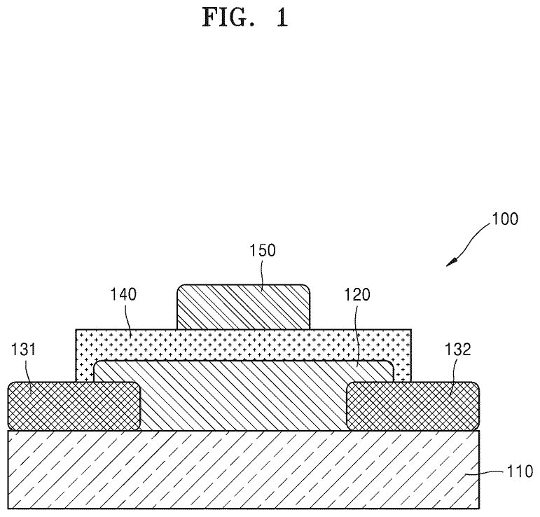

FIG. 1 schematically illustrates a semiconductor device according to at least one example embodiment.

A semiconductor device 100 includes a substrate 110, a channel 120 provided on the substrate 110, a source electrode 131 electrically connected to the channel 120, a drain electrode 132 electrically connected to the channel 120, a gate insulating layer 140 provided on the channel 120, and a gate electrode 150 provided on the gate insulating layer 140.

The source electrode 131 and the drain electrode 132 may be spaced apart from each other with the channel 120 therebetween. The channel 120 may extend onto portions of upper surfaces of the source electrode 131 and the drain electrode 132. The semiconductor device 100 may be applied to a transistor having a planar channel structure.

The substrate 110 may be a semiconductor substrate, an insulating substrate and/or a semiconductor substrate having an insulating layer formed on its surface. For example, the substrate 110 may be a semiconductor substrate. The semiconductor substrate may include an elemental and/or a compound semiconductor, for example, Si, Ge, SiGe, a group III-V semiconductor material and/or the like. For example, the substrate 110 may be a silicon substrate having silicon oxide formed on its surface, but the example embodiments are not limited thereto.

In at least one example embodiment, the channel 120 includes tellurium (Te) and oxygen (O). The channel 120 may be, for example, a p-type channel including TeₐO_{b} (where a+b=100, 70≤a≤95, and 5≤b≤30). The channel 120 may further include at least one of S, Se, In, Sn, Cu, and/or Ge. The channel 120 may include a single tellurium oxide layer or may have a structure in which Te layers and TeO layers are alternately stacked. The channel 120 may have a thickness in a range of about 1 nanometer (nm) to about 100 nm. In addition, the channel 120 may have an amorphous structure. For example, the channel 120 may also be referred to as having an amorphous p-type tellurium-based semiconductor oxide.

The source electrode 131 and the drain electrode 132 each include a conductive material (e.g., a zero-band gap material and/or a material wherein the Fermi level is within a conductive band). For example, in at least some example embodiments, the source electrode 131 and/or the drain electrode 132 may each include a metal material, such as at least one of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sn), vanadium (V), ruthenium (Ru), platinum (Pt), zinc (Zn), magnesium (Mg), an alloy thereof, and/or the like. Alternatively, the source electrode 131 and the drain electrode 132 may each include a nitride including the above materials. For example, the source electrode 131 and the drain electrode 132 may each include at least one of W, TiN, Mo, MoN, Ru, TiSiN, etc. For example, the source electrode 131 and the drain electrode 132 may each include Zn with a content of 10 atomic percent (at %) or less. Here, the Zn content may indicate the content of Zn relative to the total metal elements included in the source electrode 131, excluding oxygen.

The gate electrode 150 includes a conductive material. For example, the gate electrode 150 may at least one of a metal, a metal nitride, and a transparent conductive oxide (TCO). The gate insulating layer 140 may include an oxide containing at least one of hafnium (Hf), zirconium (Zr), aluminum (Al), and silicon (Si). In a case in which the semiconductor device 100 is a component of a memory cell, the gate electrode 150 may be a partial region of a word line and/or electrically connected to a word line.

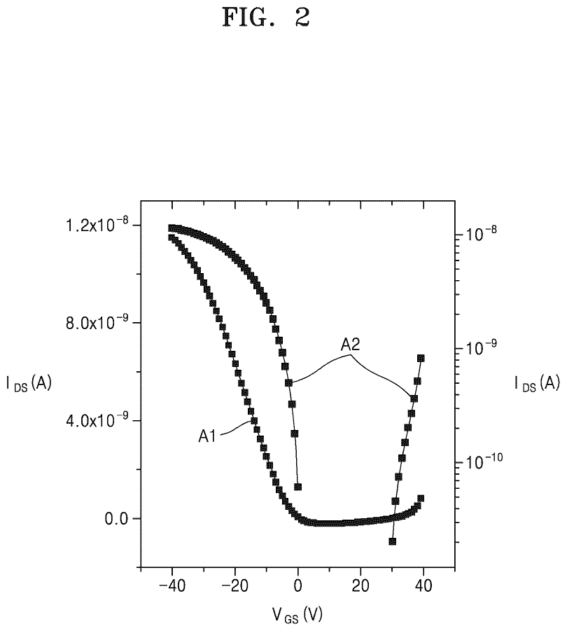

FIGS. 2, 3, and 4 show transfer curves according to variations in the oxygen content of the channel 120 of the semiconductor device.

FIG. 2 shows a transfer curve for the TeₐO_{b} channel 120 at an oxygen content of 29 at %. A Te₇₁O₂₉ channel exhibits p-type semiconductor characteristics, because an on-current appears when V_{GS} has a negative (−) value. Graph A1 is plotted on a linear scale, and graph A2 is plotted on a logarithmic scale.

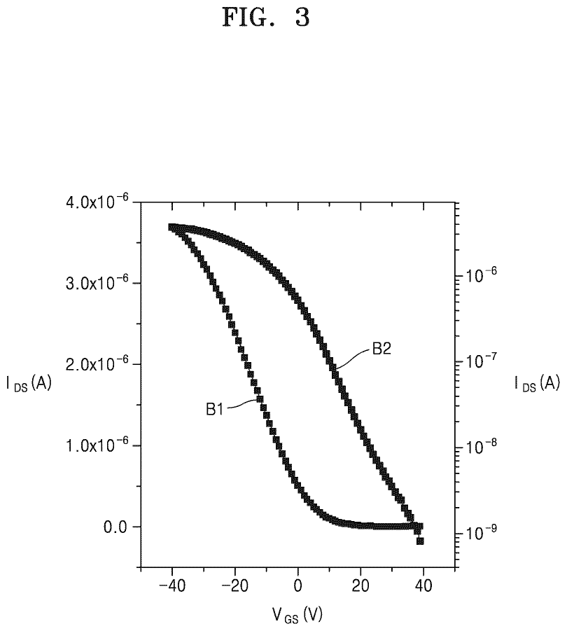

FIG. 3 shows a transfer curve in a case in which the oxygen content of the TeₐO_{b} channel 120 is 24 at %. A Te₇₆O₂₄ channel exhibits p-type semiconductor characteristics, because an on-current appears when V_{GS} has a negative (−) value. Graph B1 is plotted on a linear scale, and graph B2 is plotted on a logarithmic scale.

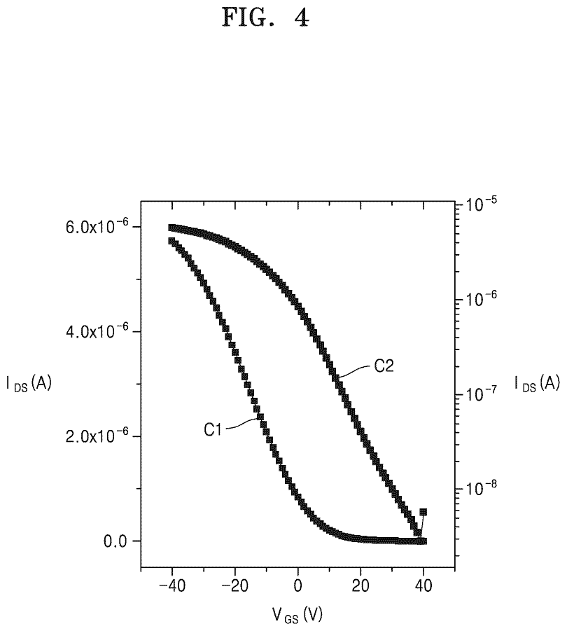

FIG. 4 shows a transfer curve for the TeₐO_{b} channel 120 at an oxygen content of 19 at %. A Te₇₁O₁₉ channel exhibits p-type semiconductor characteristics, because an on-current appears when V_{GS} has a negative (−) value. Graph C1 is plotted on a linear scale, and graph C2 is plotted on a logarithmic scale.

Referring to FIGS. 2, 3, and 4, the on-current increases as the oxygen content of the TeₐO_{b} channel 120 decreases and as the tellurium content increases. Therefore, according to at least some example embodiments, the TeₐO_{b} channel 120 may be configured such that a+b=100, 70≤a≤95, and 5≤b≤30.

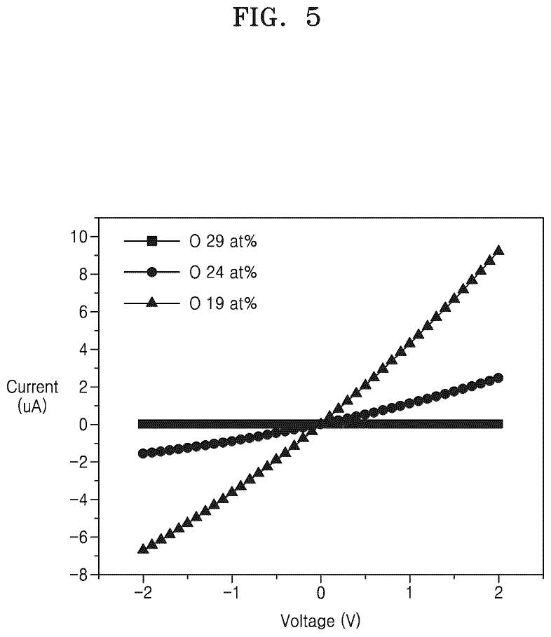

FIG. 5 shows changes in voltage-current graphs for the TeₐO_{b} channel 120 at oxygen contents of 29 at %, 24 at %, and 19 at %. Because FIG. 5 shows changes in current with respect to voltage while the gate voltage is kept constant, the trend in channel resistance may be determined by comparing the reciprocal values of the slopes of the graphs. Referring to FIG. 5, it may be confirmed that the channel resistance value decreases as the oxygen content decreases.

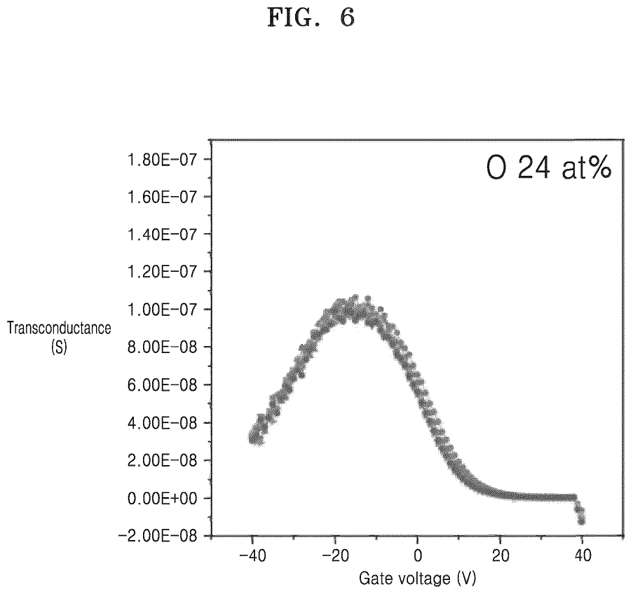

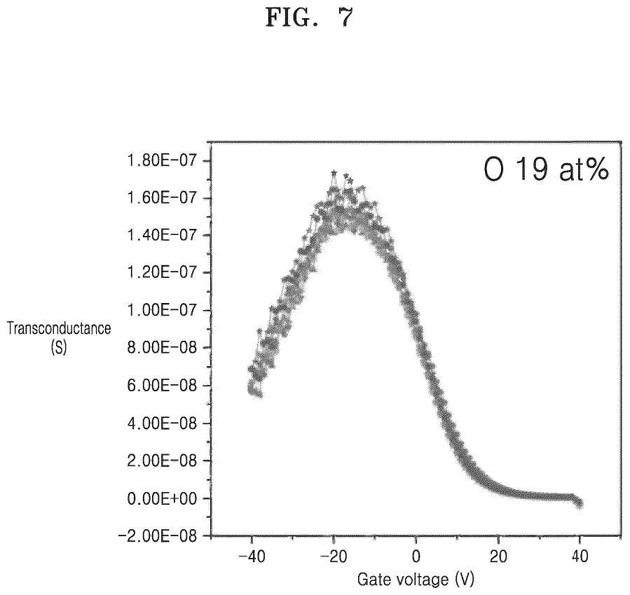

FIG. 6 shows transconductance with respect to gate voltage for the TeₐO_{b} channel 120 at an oxygen content of 24 at %. FIG. 7 shows transconductance with respect to gate voltage for the TeₐO_{b} channel 120 at an oxygen content of 19 at %. Referring to FIGS. 6 and 7, the transconductance increases as the oxygen content of the TeₐO_{b} channel 120 decreases.

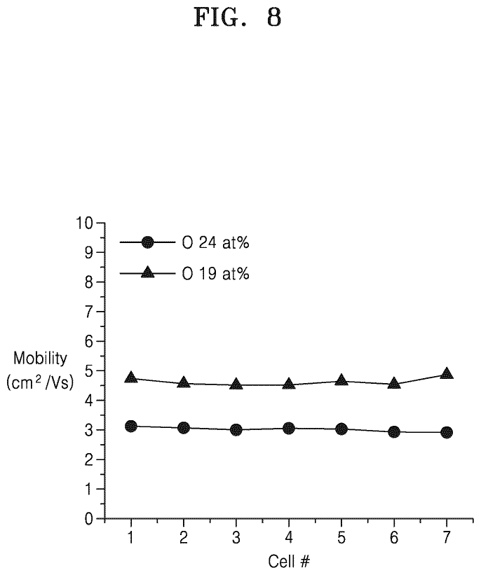

FIG. 8 shows mobility for the TeₐO_{b} channel 120 at oxygen contents of 24 at % and 19 at %. The horizontal axis of the graph represents the cell number, where each cell represents a test specimen. The TeₐO_{b} channel has a mobility of approximately 3 cm²/Vs or higher at oxygen contents of 24 at % and 19 at %, and exhibits a relatively higher mobility at an oxygen content of 19 at % compared to 24 at %. Referring to FIG. 8, the mobility increases as the oxygen content of the TeₐO_{b} channel 120 decreases.

As described above, the ratio of Te to oxygen affects the characteristics of the TeO. Therefore, the semiconductor device 100 according to at least one example embodiment may include TeₐO_{b} (where a+b=100, 70≤a≤95, and 5≤b≤30) to implement a p-type channel, and may exhibit a comparatively high on-current, a comparatively high transconductance, and a comparatively high mobility.

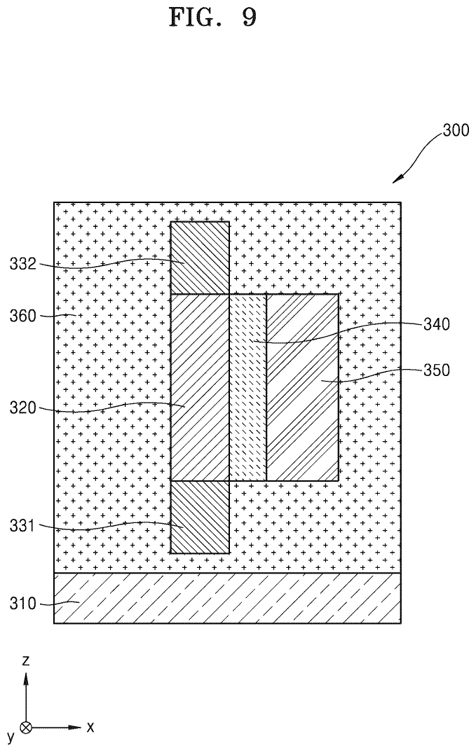

FIG. 9 illustrates a semiconductor device according to at least one example embodiment.

Referring to FIG. 9, a semiconductor device 300 includes a substrate 310, a source electrode 331 provided over the substrate 310, a drain electrode 332 spaced apart from the source electrode 331, and a channel 320 arranged between the source electrode 331 and the drain electrode 332.

The channel 320 may include TeₐO_{b} (where a+b=100, 70≤a≤95, and 5≤b≤30). The channel 320 may further include at least one of S, Se, In, Sn, Cu, and Ge. The channel 320 may include a single tellurium oxide layer or may have a structure in which Te layers and TeO layers are alternately stacked.

The source electrode 331 and the drain electrode 332 are spaced apart from each other in a direction perpendicular to the substrate 310 (Z-direction), and the source electrode 331, the channel 320, and the drain electrode 332 may be arranged sequentially in the direction perpendicular to the substrate 310 (Z-direction). The source electrode 331, the channel 320, and the drain electrode 332 may be sequentially arranged without any intervening layers. The source electrode 331, the channel 320, and the drain electrode 332 may have the same width. The channel 320 may be arranged such that its longitudinal direction extends in the direction perpendicular to the substrate 310 (Z-direction). As used herein, the term “longitudinal direction” refers to the direction along the longer dimension of the corresponding component as viewed in the drawings. The semiconductor device 300 may be applied to a vertical channel transistor.

A gate electrode 350 may be provided on one side of the channel 320. A gate insulating layer 340 may be provided between the channel 320 and the gate electrode 350. The gate electrode 350 may be arranged such that its longitudinal direction (Z-direction) is identical to the direction perpendicular to the substrate 310. The channel 320, the gate insulating layer 340, and the gate electrode 350 may be arranged in a line in a direction parallel to the substrate 310 (X-direction). A mold insulating layer 360 may be provided on the substrate 310, filling empty spaces. The source electrode 331 may be provided spaced apart from the substrate 310 by the mold insulating layer 360. The source electrode 331, the drain electrode 332, and the gate electrode 250 may each include a conductive material.

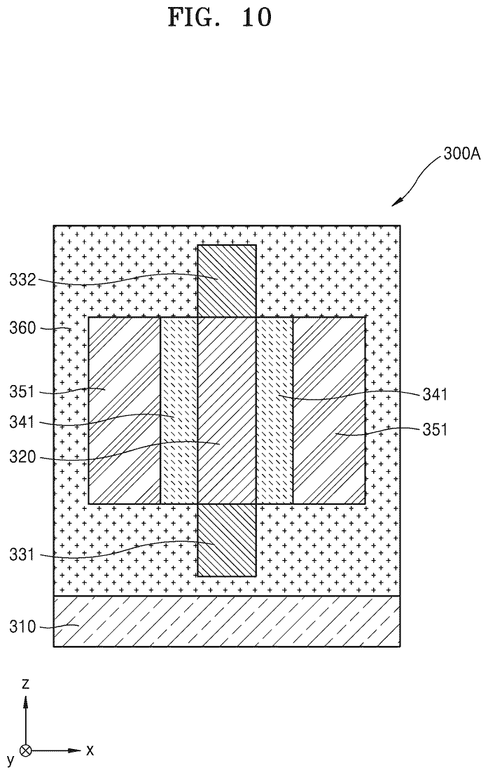

FIG. 10 illustrates another example of a semiconductor device. In FIG. 10, components assigned the same reference numerals as in FIG. 9 have substantially the same (or substantially similar) configurations and operational effects as those described above with reference to FIG. 9, and thus, detailed descriptions thereof will be omitted.

A semiconductor device 300A includes the source electrode 331, the channel 320, and the drain electrode 332, which are arranged sequentially in the direction perpendicular to the substrate 310 (Z-direction). A gate insulating layer 341 is provided at a perimeter of the channel 320, and a gate electrode 351 may be provided at a perimeter of the gate insulating layer 341. The gate electrode 351 may be provided at a perimeter of the channel 320 to increase the facing area between the gate electrode 351 and the channel 320 and improve short channel effects. The semiconductor device 300A may be applied to a gate-all-around transistor.

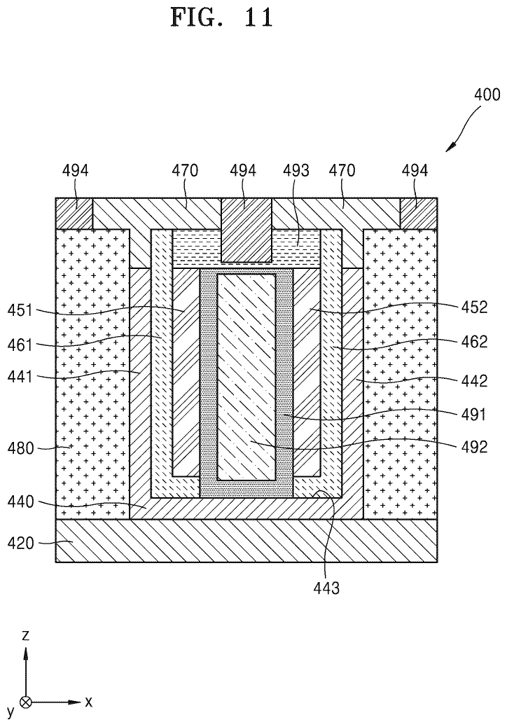

FIG. 11 illustrates a semiconductor device according to at least one example embodiment.

Referring to FIG. 11, a semiconductor device 400 may include a source electrode 420 and a channel 440 provided on the source electrode 420. The channel 440 may include TeₐO_{b} (where a+b=100, 70≤a≤95, and 5≤b≤30). The channel 440 may further include at least one of S, Se, In, Sn, Cu, and Ge. The channel 440 may include a single tellurium oxide layer or may have a structure in which Te layers and TeO layers are alternately stacked.

The channel 440 may have a U-shaped cross-sectional shape. The channel 440 may include a bottom portion 443 connected to the source electrode 420, a first vertical extension portion 441 extending from one end of the bottom portion 443 in a direction perpendicular to the source electrode 420 (Z-direction), and a second vertical extension portion 442 extending from another end of the bottom portion 443 in the direction perpendicular to the source electrode 420 (Z-direction).

A first gate electrode 451 may be spaced apart from the first vertical extension portion 441, and a second gate electrode 452 may be spaced apart from the second vertical extension portion 442. A first gate insulating layer 461 may be provided between the first vertical extension portion 441 and the first gate electrode 451, and a second gate insulating layer 462 may be provided between the second vertical extension portion 442 and the second gate electrode 452.

At least one of the first gate electrode 451 and the second gate electrode 452 may extend in a second horizontal direction (y-direction). The first gate electrode 451 and the second gate electrode 452 may be spaced apart from each other. At least one of the first gate electrode 451 and the second gate electrode 452 may constitute a word line WL. An electrical signal input to the first gate electrode 451 may differ from an electrical signal input to the second gate electrode 452. The first gate electrode 451 may control the first vertical extension portion 441 of the channel 440, and the second gate electrode 452 may control the second vertical extension portion 442 of the channel 440.

An insulating liner 491 may be arranged between the first gate electrode 451 and the second gate electrode 452, which are spaced apart from each other. The insulating liner 491 may be conformally arranged on sidewalls of the first gate electrode 451 and the second gate electrode 452 that face each other, and/or on an upper surface of the channel 440. The insulating liner 491 may have an upper surface that is coplanar with the first gate electrode 451 and the second gate electrode 452. For example, the insulating liner 491 may include silicon nitride. A gap-fill insulating layer 492 may fill a space on the insulating liner 491 between the first gate electrode 451 and the second gate electrode 452, which are spaced apart from each other. For example, the gap-fill insulating layer 492 may include silicon oxide. An upper insulating layer 493 may be arranged on upper surfaces of the first gate electrode 451, the second gate electrode 452, and/or the gap-fill insulating layer 492. An upper surface of the upper insulating layer 493 may be arranged at the same level as an upper surface of a mold insulating layer 480.

A drain electrode 470 may be arranged over the channel 440. The drain electrode 470 may be configured to function as a landing pad. The drain electrode 470 may include a left drain electrode and a right drain electrode. The left drain electrode 470 may be electrically connected to the first vertical extension portion 441. The right drain electrode 470 may be electrically connected to the second vertical extension portion 442. The left drain electrode and the right drain electrode may not be electrically connected to each other. The drain electrode 470 may include an upper portion and a lower portion. The upper portion of the drain electrode 470 may be a portion arranged at a level higher than the upper surface of the mold insulating layer 480. The lower portion of the drain electrode 470 may be a portion arranged inside a drain electrode recess defined between the mold insulating layer 480 and the upper insulating layer 493. In at least one example embodiment, the upper portion of the drain electrode 470 may have a first width W1 in a first horizontal direction (x-direction), and the lower portion of the drain electrode 470 may have a second width W2 in the first horizontal direction (x-direction), which is less than the first width W1. The lower portion of the drain electrode 470 may be arranged inside the drain electrode recess, and the upper portion of the drain electrode 470, on the lower portion of the drain electrode 470, may have a bottom surface arranged on the upper surfaces of the mold insulating layer 480 and the upper insulating layer 493, and accordingly, the drain electrode 470 may have a T-shaped vertical cross-section. The bottom surface of the lower portion of the drain electrode 470 may be in contact with upper surfaces of the first vertical extension portion 441 and/or the second vertical extension portion 442. Opposite sidewalls of the lower portion of the drain electrode 470 may be aligned with opposite sidewalls of the first vertical extension portion 441 and the second vertical extension portion 442. The bottom surface of the lower portion of the drain electrode 470 may be arranged at a level higher than the upper surfaces of the first gate electrode 451 and/or the second gate electrode 452, and portions of sidewalls of the lower portion of the drain electrode 470 may be covered by the first gate insulating layer 461 and/or the second gate insulating layer 462. A drain electrode insulating layer 494 surrounding the drain electrode 470 may be arranged on upper surfaces of the mold insulating layer 480 and the upper insulating layer 493. The semiconductor device 400 may have a vertical channel transistor (VCT) structure including a vertical channel region where the channel 440 extends in a vertical direction (Z-direction) from the source electrode 420.

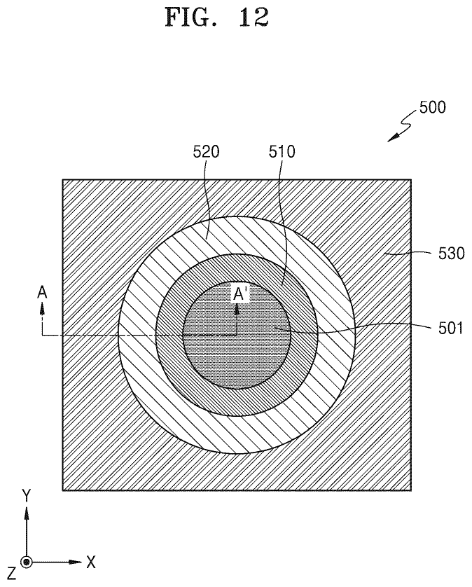

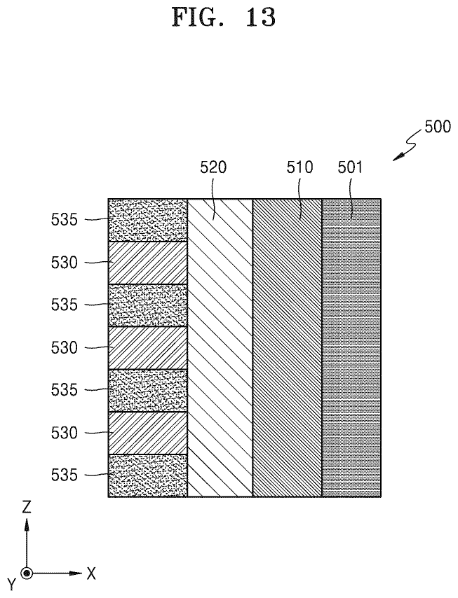

FIGS. 12 and 13 are a horizontal cross-sectional view and a vertical cross-sectional view, respectively, schematically illustrating a structure of a memory cell string of a memory apparatus, according to at least one example embodiment. Referring to FIG. 12, a memory cell string of a memory apparatus 500 according to at least one example embodiment may include a center fill material 501, a channel 510, a ferroelectric layer 520, and a gate electrode 530 that are arranged concentrically on an XXY plane. The channel 510 may include TeₐO_{b} (where a+b=100, 70≤a≤95, and 5≤b≤30). The channel 510 may further include at least one of S, Se, In, Sn, Cu, and Ge. The channel 510 may include a single tellurium oxide layer or may have a structure in which Te layers and TeO layers are alternately stacked.

The channel 510 may be arranged to surround the center fill material 501, the ferroelectric layer 520 may be arranged to surround the channel 510, and the gate electrode 530 may be arranged to surround the ferroelectric layer 520. The center fill material 501 may fill a space inside an inner wall of the channel 510 to support the channel 510 and the memory cell string. However, the center fill material 501 is not an essential component and may be omitted. In this case, an empty space may exist instead of the center fill material 501.

FIG. 13 schematically illustrates a cross-sectional view in a first direction (e.g., the Z-axis direction), taken along line A-A′ in FIG. 12 from the center of the center fill material 501 to the gate electrode 530. Referring to FIG. 13, the memory apparatus 500 may include a plurality of gate electrodes 530, and the plurality of gate electrodes 530 may be spaced apart from one another in the first direction. In addition, spacers 535 may be arranged between the plurality of gate electrodes 530. That is, the plurality of gate electrodes 530 and a plurality of spacers 535 may be alternately arranged in the first direction. The memory apparatus 500 may include the channel 510 spaced apart from and facing the plurality of gate electrodes 530 and the plurality of spacers 535 in a second direction (e.g., the X-axis direction) perpendicular to the first direction, and continuously extending in the first direction, and the ferroelectric layer 520 continuously extending in the first direction and arranged between the channel 510 and the plurality of gate electrodes 530. In addition, the memory apparatus 500 may further include the center fill material 501 continuously extending in the first direction inside the channel 510. In other words, the ferroelectric layer 520, the channel 510, and the center fill material 501 may be sequentially arranged in the second direction from the plurality of gate electrodes 530 and the plurality of spacers 535. Each of the plurality of spacers 535 may include insulating material such as silicon oxide (SiO₂), but is not limited thereto).

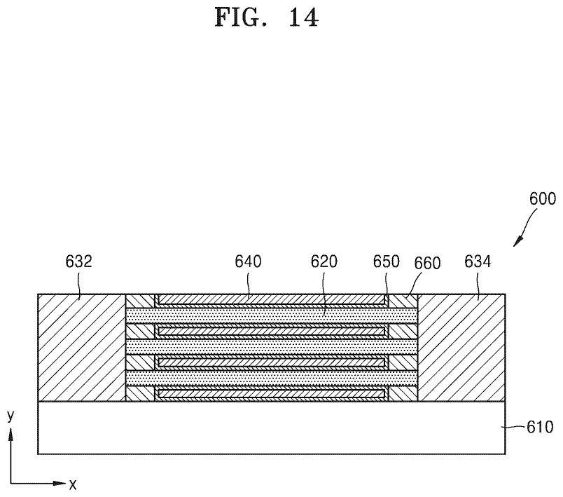

FIG. 14 is a diagram illustrating a semiconductor device 600 according to at least one example embodiment. The semiconductor device 600 includes a plurality of channels 620 arranged over a substrate 610, a source electrode 632 and a drain electrode 634 both in contact with the plurality of channels 620, and a plurality of gate electrodes 640 spaced apart from the plurality of channels 620. Each of the plurality of channels 620 may include TeₐO_{b} (where a+b=100, 70≤a≤95, and 5≤b≤30). Each of the plurality of channels 620 may further include at least one of S, Se, In, Sn, Cu, and Ge. Each of the plurality of channels 620 may include a single tellurium oxide layer or may have a structure in which Te layers and TeO layers are alternately stacked.

The substrate 610 may be a semiconductor substrate, an insulating substrate, and/or a semiconductor substrate having an insulating layer formed on its surface. The semiconductor substrate may include, for example, Si, Ge, SiGe, or the like. For example, the substrate 610 may be a silicon substrate having silicon oxide formed on its surface, but is not limited thereto.

On the substrate 610, the source electrode 632 and the drain electrode 634 may be spaced apart from each other in a first direction (X-direction), and the plurality of channels 620 may be spaced apart from one another between the source electrode 632 and the drain electrode 634 in a second direction (Y-direction).

The plurality of gate electrodes 640 may be spaced apart from the channels 620, respectively, and a ferroelectric layer 650 may be arranged between each gate electrode 640 and the respective channel 620. For example, the ferroelectric layer 650 may be provided to surround at least a portion of the gate electrode 640. For example, the gate electrode 640 and the channel 620 may be alternately arranged in the second direction (Y-direction), and the ferroelectric layer 650 may surround the gate electrodes 640. The ferroelectric layer 650 may act as an insulator between the channel 620 and the gate electrode 640 and suppress leakage current.

Each channel 620 may be in edge contact with the source electrode 632 and the drain electrode 634. For example, opposite ends of the channel 620 may be in contact with the source electrode 632 and the drain electrode 634, respectively.

In addition, each gate electrode 640 may be spaced apart from the source electrode 632 and the drain electrode 634, and spacers 660 may be further arranged between the gate electrodes 640 and the source electrode 632 and between the gate electrodes 640 and the drain electrode 634. Because the source electrode 632, the gate electrodes 640, and the drain electrode 634 are arranged in the first direction (X-direction), parasitic capacitance may occur between the source electrode 632 and the gate electrodes 640 and between the gate electrodes 640 and the drain electrode 634. To reduce the parasitic capacitance, the spacers 660 may include, for example, a boron nitride film. The boron nitride film does not have porosity but has mechanical strength, and thus may securely support the channels 620 arranged on the spacers 660.

The semiconductor device 600 may have a multi-bridge structure in which the plurality of channels 620 are each in contact with the source electrode 632 and the drain electrode 634, and are stacked spaced apart from one another in a direction away from the substrate 610. Such a multi-bridge channel may reduce short channel effects and reduce the area occupied by the source/drain, and thus is advantageous for high integration. In addition, because uniform source/drain junction capacitance may be maintained regardless of channel position, there is an advantage in that the channel may be applied as a high-speed and high-reliability device. The semiconductor device 600 may be applied to a so-called gate-all-around (GAA) transistor. The semiconductor device 600 may be applied as, for example, a logic device or a memory device.

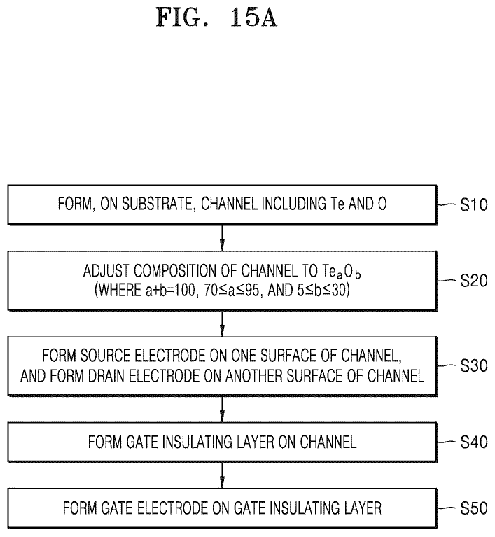

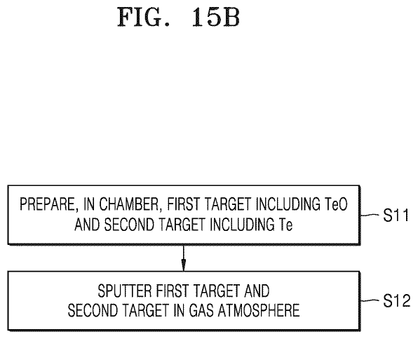

FIG. 15A is a diagram for describing a method of manufacturing a semiconductor device, according to at least one example embodiment.

Referring to FIG. 15A, according to the method of manufacturing a semiconductor device, a channel including Te and O is formed on a substrate (S10). The forming of the channel may be performed via a deposition process (e.g., at least one of physical vapor deposition, chemical vapor deposition, atomic layer deposition, and/or the like). The composition of the channel is adjusted to TeₐO_{b} (where a+b=100, 70≤a≤95, and 5≤b≤30) (S20).

A source electrode is formed on one surface of the channel, and a drain electrode is formed on another surface of the channel (S30). Then, a gate insulating layer is formed on the channel (S40). A gate electrode is formed on the gate insulating layer (S50). In this manner, a semiconductor device having a p-type channel may be manufactured.

FIG. 15B is a diagram for describing an example of a method of forming a channel.

The forming of the channel includes preparing, in a chamber, a first target including TeO and a second target including Te (S11). Then, the first target and the second target are sputtered in a gas atmosphere (S12). The gas may include, for example, argon (Ar) gas. The first target and the second target may be prepared in the same chamber, and then the first target and the second target may each be sputtered in the gas atmosphere. The deposition amount of O from TeO in the first target may be controlled. In the present embodiment, a co-sputtering method using a plurality of targets may be used.

As described above, in method of manufacturing a semiconductor device according to at least one example embodiment, a p-type channel including Te and O may be formed by using a plurality of targets.

The semiconductor device according to at least one example embodiment exhibits excellent on-current and mobility, and thus may be applied to various electronic apparatuses such as two-transistor, zero-capacitor (2T0C) dynamic random-access memory (DRAM), monolithic three-dimensional (M3D) logic circuits, displays, or gas sensors.

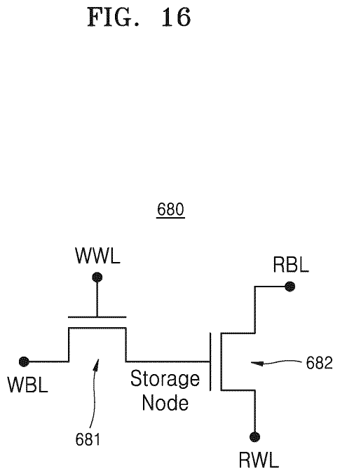

FIG. 16 illustrates an example where a semiconductor device is applied to a memory apparatus, according to at least one example embodiment. Referring to FIG. 16, a memory apparatus 680 may include a first transistor 681 and a second transistor 682. The semiconductor device 100, 300, 300A, 400, 500, or 600 described above with reference to FIGS. 1 to 14 may be applied to at least one of the first transistor 681 and the second transistor 682. The memory apparatus 680 may be so-called 2T0C DRAM. In other words, the memory apparatus 680 may have a capacitorless structure including two transistors. The memory apparatus 680 may use the first transistor 681 and the second transistor 682 to store data, and retain the data even without a capacitor. The memory apparatus 680 may be connected to a write bit line (WBL), a write word line (WWL), a read word line (RWL), and a read bit line (RBL). For example, the write bit line WBL may be connected to a source electrode of the first transistor 681, the write word line WWL may be connected to a gate of the first transistor 681, and a drain electrode of the first transistor 681 may be connected to a gate of the second transistor. The read bit line RWL and the read word line RWL may be, respectively, connected to a drain electrode and a source electrode of the second transistor 682.

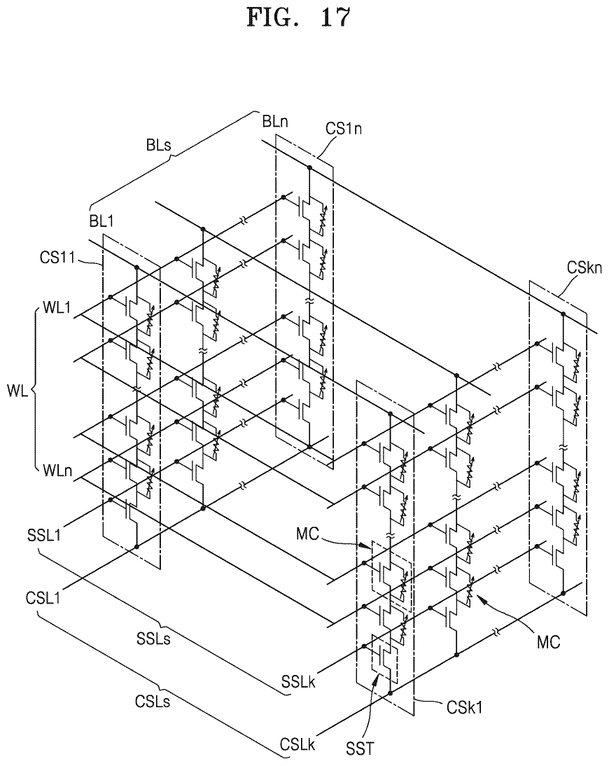

FIG. 17 is a diagram illustrating an equivalent circuit of a memory apparatus according to at least one example embodiment.

Referring to FIG. 17, the memory apparatus may include a plurality of memory cell strings CS11 to CSkn. The plurality of memory cell strings CS11 to CSkn may be arranged two-dimensionally in row and column directions to form rows and columns. Each of the memory cell strings CS11 to CSkn may include a plurality of memory cells MC and a plurality of string selection transistors SST. In each of the memory cell strings CS11 to CSkn, the memory cells MC and the string selection transistors SST may be stacked in a height direction. Within each of the memory cell strings CS11 to CSkn, the memory cells MC may correspond to a circuit in which a transistor and a resistor are connected in parallel. For example, each of the memory cell strings CS11 to CSkn may be the memory cell string illustrated in FIGS. 12 and 13.

Rows of the plurality of memory cell strings CS11 to CSkn may be respectively connected to different string selection lines SSL1 to SSLk. For example, the string selection transistors SST of the memory cell strings CS11 to CS1n are commonly connected to the string selection line SSL1. The string selection transistors SST of the memory cell strings CSk1 to CSkn are commonly connected to the string selection line SSLk.

In addition, columns of the plurality of memory cell strings CS11 to CSkn are respectively connected to different bit lines BL1 to BLn. For example, the memory cells MC and the string selection transistors SST of the memory cell strings CS11 to CSk1 may be commonly connected to the bit line BL1, and the memory cells MC and the string selection transistors SST of the memory cell strings CS1n to CSkn may be commonly connected to the bit line BLn.

In addition, the rows of the plurality of memory cell strings CS11 to CSkn may be respectively connected to different common source lines CSL1 to CSLk. For example, the string selection transistors SST of the plurality of memory cell strings CS11 to CS1n may be commonly connected to the common source line CSL1, and the string selection transistors SST of the plurality of memory cell strings CSk1 to CSkn may be commonly connected to the common source line CSLk.

The memory cells MC located at the same (or a substantially similar) height from the substrate (or the string selection transistors SST) may be commonly connected to one word line WL, and the memory cells MC located at different heights may be respectively connected to different word lines WL1 to WLm.

In this structure, write and read operations may be performed in units of rows of the memory cell strings CS11 to CSkn. For example, the memory cell strings CS11 to CSkn may be selected in units of one row by common source lines CSLs, and the memory cell strings CS11 to CSkn may be selected in units of one row by string selection lines SSLs. Then, in a selected row of the memory cell strings memory cell strings CS11 to CSkn, write and read operations may be performed in units of pages. For instance, a page may be one row of memory cells MC connected to one word line WL. In the selected row of the memory cell strings CS11 to CSkn, the memory cells MC may be selected in units of pages by the word lines WL.

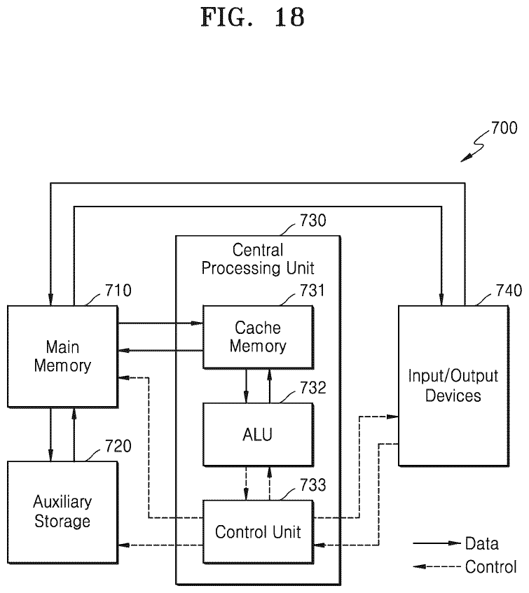

In addition, the semiconductor device 100 according to at least one example embodiment may be used for data storage in various electronic apparatuses. FIG. 18 is a conceptual diagram schematically illustrating a device architecture applicable to an electronic apparatus, according to embodiments. Referring to FIG. 18, an electronic apparatus 700 may include a main memory 710, an auxiliary storage 720, a central processing unit (CPU) 730, and input/output devices 740. The CPU 730 may include a cache memory 731, an arithmetic logic unit (ALU) 732, and a control unit 733. The cache memory 731 may include static random-access memory (SRAM). The main memory 710 may include a DRAM device, and the auxiliary storage 720 may include the semiconductor device and/or the memory apparatus 100, 300, 300A, 400, 500, or 600 according to at least one example embodiment. Alternatively, all of the cache memory 731, the main memory 710, and the auxiliary storage 720 may include the semiconductor device and/or the memory apparatus 100, 300, 300A, 400, 500, or 600 according to at least one example embodiment. In some cases, the electronic apparatus 700 may be implemented such that computing unit devices and memory unit devices are adjacent to each other on a single chip, without the distinction between the above-described sub-units.

Some of the elements and/or functional blocks disclosed above may be implemented as: processing circuitry, such as hardware including logic circuits; a hardware/software combination, such as software for executing a processor; or a combination thereof. For example, the processing circuitry may include a CPU, an ALU, a digital signal processor, a microcomputer, a field-programmable gate array (FPGA), a system-on-chip (SoC), a programmable logic unit, a microprocessor, an application-specific integrated circuit (ASIC), and/or the like. The processing circuitry may include electronic components, for example, at least one of a transistor, a resistor, a capacitor, and/or the like. In at least some example embodiments, the processing circuitry may include electronic components, for example, at least one logic gate among an AND gate, an OR gate, a NAND gate, a NOR gate, and/or the like.

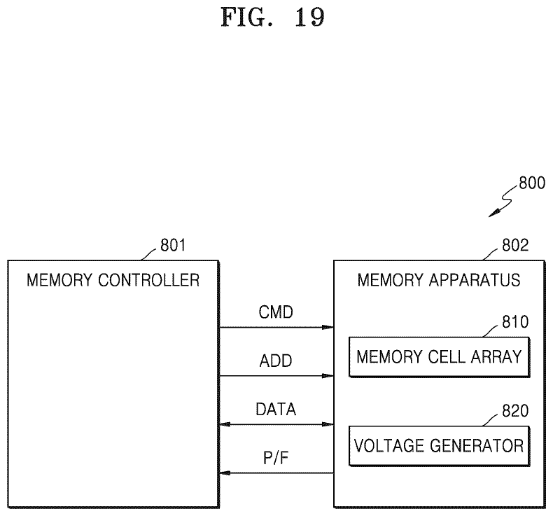

FIG. 19 is a block diagram of a memory system 800 according to at least one example embodiment.

Referring to FIG. 19, the memory system 800 may include a memory controller 801 and a memory apparatus 802. The memory controller 801 performs control operations on the memory apparatus 802, and for example, the memory controller 801 provides the memory apparatus 802 with an address ADD and a command CMD to perform programming (or write), read, and/or erase operations on the memory apparatus 802. In addition, data for programming operations and reading may be transferred between the memory controller 801 and the memory apparatus 802.

The memory apparatus 802 may include a memory cell array 810 and a voltage generator 820. The memory cell array 810 may include a plurality of memory cells and may include the semiconductor device 100, 300, 300A, 400, 500, or 600 according to the above-described embodiments.

The memory controller 801 may include: processing circuitry, such as hardware including logic circuits; a hardware/software combination, such as a processor capable of executing software; or a combination thereof. In more detail, for example, the processing circuitry may be, but is not limited to, a CPU, an ALU, a digital signal processor, a microcomputer, an FPGA, an SoC, a programmable logic unit, a microprocessor, an ASIC, or the like. The memory controller 801 may operate in response to a request from a host (not shown) and may be converted into a special-purpose controller by accessing the memory apparatus 802 and controlling the control operations described above (e.g., write/read operations). The memory controller 801 may generate the address ADD and the command CMD for performing programming/read/erase operations on the memory cell array 810. In addition, in response to a command from the memory controller 801, the voltage generator 820 (e.g., a power circuit) may generate a voltage control signal for controlling a voltage level of a word line for data programming or data reading on the memory cell array 810.

In addition, the memory controller 801 may perform a determination operation on data read from the memory apparatus 802. For example, based on data read from memory cells, the number of on-cells and/or the number of off-cells may be determined. The memory apparatus 802 may provide a pass/fail signal P/F to the memory controller 801 according to a result of reading the read data. The memory controller 801 may control write and read operations of the memory cell array 810 by referring to the pass/fail signal P/F.

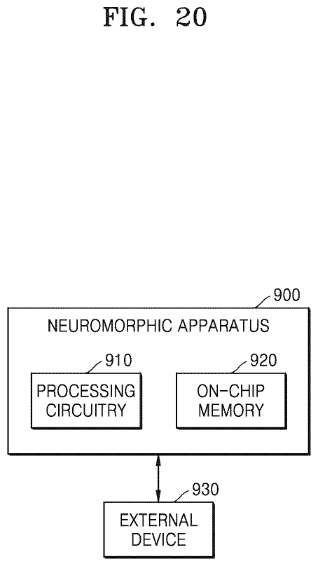

FIG. 20 is a block diagram illustrating a neuromorphic apparatus 900 and an external device connected thereto, according to at least one example embodiment.

Referring to FIG. 20, the neuromorphic apparatus 900 may include processing circuitry 910 and/or on-chip memory 920. The on-chip memory 920 may include the semiconductor device 100, 200, 300, 300A, 300B, 300C, 400, 500, or 600 according to the above-described embodiments.

In some embodiments, the processing circuitry 910 may be configured to control functions for driving the neuromorphic apparatus 900. For example, the processing circuitry 910 may be configured to execute a program stored in the on-chip memory 920 to control the neuromorphic apparatus 900. In some embodiments, the processing circuitry 910 may include hardware such as logic circuits, a hardware/software combination such as a processor capable of executing software, or a combination thereof. For example, the processor may include, but is not limited to, a CPU, a graphics processing unit (GPU), an application processor (AP) included in the neuromorphic device 900, an ALU, a digital signal processor, a microcomputer, an FPGA, an SoC, a programmable logic unit, a microprocessor, an ASIC, or the like. In some embodiments, the processing circuitry 910 may be configured to read/write various pieces of data from/to an external device 930, and/or execute the neuromorphic apparatus 900 by using the read/written data. In some embodiments, the external device 930 may include an external memory having an image sensor (e.g., a complementary metal-oxide-semiconductor (CMOS) image sensor circuit) and/or a sensor array.

In some example embodiments, the neuromorphic apparatus 900 may be applied to a machine learning system. The machine learning system may use various artificial neural network architectures and processing models, such as a convolutional neural network (CNN), a deconvolutional neural network, a recurrent neural network (RNN) optionally including long short-term memory (LSTM) units and/or gated recurrent units (GRUs), a stacked neural network (SNN), a state-space dynamic neural network (SSDNN), a deep belief network (DBN), a generative adversarial network (GAN), and/or a restricted Boltzmann machine (RBM).

Alternatively and/or additionally, such machine learning systems may include other types of machine learning models, for example, linear and/or logistic regression, statistical clustering, Bayesian classification, decision trees, dimensionality reduction such as principal component analysis, and expert systems, and/or combinations thereof, including ensembles such as random forests. Such machine learning models may be used to provide various services and/or applications, and for example, an image classification service, a user authentication service based on biometric information or biometric data, an advanced driver-assistance system (ADAS) service, a voice assistance service, an automatic speech recognition (ASR) service, or the like may be executed by electronic apparatuses.

A semiconductor device according to at least one example embodiment may be used in transistors, photovoltaic cells, thermoelectric elements, light-emitting diodes, displays, and/or the like, and may also be used in DRAM, flash memory, CMOS image sensors, and/or the like.

The above-described embodiments are merely examples, and various modifications and equivalent other embodiments are possible from those skilled in the art. Therefore, the true technical protection scope according to the embodiments should be determined by the technical spirit described in the following claims.

A semiconductor device according to at least one example embodiment may implement a p-type channel including tellurium oxide. The semiconductor device according to at least one example embodiment may exhibit p-type channel characteristics by adjusting the composition of tellurium oxide. Thus, the semiconductor device according to at least one example embodiment may be applied to various logic circuit devices.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel comprising TeₐO_{b}, wherein a+b=100, 70≤a≤95, and 5≤b≤30;
a source electrode electrically connected to the channel;
a drain electrode electrically connected to the channel and spaced apart from the source electrode;
a gate electrode on the channel; and
a gate insulating layer between the channel and the gate electrode.

2. The semiconductor device of claim 1, wherein the channel has a structure in which a plurality of Te layers is alternately stacked with a plurality of TeO layers.

3. The semiconductor device of claim 1, wherein the channel further comprises at least one of S, Se, In, Sn, Cu, or Ge.

4. The semiconductor device of claim 1, wherein the source electrode is spaced apart from the drain electrode in a vertical direction, and
the channel, the gate insulating layer, and the gate electrode are arranged in a horizontal direction, the horizontal direction longitudinal to the vertical direction.

5. The semiconductor device of claim 1, wherein the channel comprises
a bottom portion in contact with the source electrode,
a first vertical extension portion extending from one end of the bottom portion in a vertical direction perpendicular to the source electrode, and
a second vertical extension portion extending from another end of the bottom portion in the vertical direction.

6. The semiconductor device of claim 1, wherein the gate insulating layer comprises a ferroelectric material.

7. The semiconductor device of claim 6, wherein the gate electrode is a first gate electrode,
the semiconductor device further comprises a second gate electrode spaced apart from the first gate electrode, and a spacer is between the first gate electrode and the second gate electrode,
the gate insulating layer is concentric with the channel, and
the first gate electrode and the second gate electrode are concentric with the gate insulating layer.

8. The semiconductor device of claim 1, wherein the channel is one of a plurality of channels, and
the semiconductor device has a multi-bridge structure in which the plurality of channels are each in contact with the source electrode and the drain electrode and are stacked spaced apart from each other in a vertical direction perpendicular to a substrate.

9. An electronic apparatus comprising:
a host;
a memory device comprising at least one semiconductor device; and
a memory controller configured to control the memory device in response to a request from the host
wherein the at least one semiconductor device comprises a channel comprising TeₐO_{b}, wherein a+b=100, 70≤a≤95, and 5≤b≤30, a source electrode electrically connected to the channel, a drain electrode electrically connected to the channel and spaced apart from the source electrode, a gate electrode on the channel, and a gate insulating layer between the channel and the gate electrode.

10. The electronic apparatus of claim 9, wherein the channel has a structure in which a plurality of Te layers is alternately stacked with a plurality of TeO layers.

11. The electronic apparatus of claim 9, wherein the channel further comprises at least one of S, Se, In, Sn, Cu, or Ge.

12. The electronic apparatus of claim 9, wherein the source electrode is spaced apart from the drain electrode in a vertical direction, and
the channel, the gate insulating layer, and the gate electrode are arranged in a horizontal direction, the horizontal direction longitudinal to the vertical direction.

13. The electronic apparatus of claim 9, wherein the channel comprises
a bottom portion in contact with the source electrode,
a first vertical extension portion extending from one end of the bottom portion in a vertical direction perpendicular to the source electrode, and
a second vertical extension portion extending from another end of the bottom portion in the vertical direction.

14. The electronic apparatus of claim 9, wherein the gate electrode is a first gate electrode,
the at least one semiconductor device further including a second gate electrode spaced apart from the first gate electrode, and a spacer is between the first gate electrode and the second gate electrode,
the gate insulating layer is concentric with the channel, and
the first gate electrode and the second gate electrode are concentric with the gate insulating layer.

15. The electronic apparatus of claim 9, wherein the memory device comprises a dynamic random-access memory (DRAM) device having a two-transistor, zero-capacitor (2T0C) structure.

16. A method of manufacturing a semiconductor device, the method comprising:
forming a channel comprising Te and O on a substrate;
adjusting a composition of the channel to TeₐO_{b}, where a+b=100, 70≤a≤95, and 5≤b≤30;
forming a source electrode and a drain electrode on the channel;
forming a gate insulating layer on the channel; and
forming a gate electrode on the gate insulating layer such that the gate insulating layer separates the gate electrode and the channel.

17. The method of claim 16, wherein the forming of the channel comprises:
preparing a first target comprising TeO and a second target comprising Te; and
sputtering the first target and the second target in a gas atmosphere.

18. The method of claim 17, further comprising:
controlling a deposition amount of oxygen from the TeO in the first target.

19. The method of claim 16, wherein the forming the channel includes forming the channel such that the channel has a structure in which a plurality of Te layers is alternately stacked with a plurality of TeO layers.

20. The method of claim 16, wherein the forming the channel includes forming the channel such that the channel further comprises at least one of S, Se, In, Sn, Cu, or Ge.
